(19) United States
(12) Patent Application Publication
(10) Pub. No.: US 2015/0305176 A1
(43) Pub. Date: Oct. 22, 2015

(54) Wireless Device Skin

(71) Applicant: ILV Entertainment, LLC, Las Vegas, NV (US)

(72) Inventors: Byron Del Castillo, Las Vegas, NV (US); Diane Ginsburg, Las Vegas, NV (US)

(21) Appl. No.: 14/553,943

(22) Filed: Nov. 25, 2014

Related U.S. Application Data
(60) Provisional application No. 61/909,167, filed on Nov. 26, 2013.

(51) Int. Cl. H05K 5/02; H04B 1/401; H05K 5/00

(52) U.S. Cl. CPC H05K 5/0204; H05K 5/0004; H04B 1/401

(57) ABSTRACT

A wireless device skin houses a wireless device such as a wireless router or WiFi access point. The wireless device skin includes a mounting plate having a first side and a second side, the first side being mountable to a surface; an inner shell that is mounted onto the second side of the mounting plate, the inner shell and the mounting plate forming a housing in which the wireless device is disposed, and the inner shell including a center aperture; an outer skin that is releasably mounted onto the second side of the mounting plate, the outer skin covering the inner shell, and the outer skin including a center aperture; and a center disk configured to pass through the center aperture of the outer skin and close the center aperture of the inner shell.

### 1. CROSS REFERENCE TO RELATED APPLICATIONS

This application claims the benefit of and priority to U.S. Provisional Application No. 61/909,167 filed Nov. 26, 2013, the contents of which are hereby incorporated by reference.

### 2. FIELD

The disclosed embodiments relate to housings and skins for housings that cover wireless devices.

### 3. RELATED ART

Wireless devices that are installed in a home, office, or other private, government, or commercial building are common place. Such devices may include wireless routers that provide wireless internet connection commonly known as WiFi to computing devices within the building. Such wireless devices typically come in very few colors and shapes. Most often, a wireless router will be available in black, white, or grey in a rectangular shape. Other possible configurations are generally not offered. Further, it is not easy to change the appearance of the chosen wireless device after it is produced.

### SUMMARY

The disclosed embodiments have been made in light of the above problems and aspects of the invention may include a wireless device skin that houses a wireless device. The wireless device skin may include a mounting plate having a first side and a second side, the first side being mountable to a surface; an inner shell that is mounted onto the second side of the mounting plate, the inner shell and the mounting plate forming a housing in which the wireless device is disposed, and the inner shell including a center aperture; an outer skin that is releasably mounted onto the second side of the mounting plate, the outer skin covering the inner shell, and the outer skin including a center aperture; and a center disk configured to pass through the center aperture of the outer skin and close the center aperture of the inner shell.

According to further aspects, the wireless device disposed within the housing may be mounted to the second side of the mounting plate. Further, the inner shell and the outer skin may comprise control input holes allowing access to controls of the wireless device. The mounting plate may include at least one mounting hole facilitating the mounting plate being mounted to the surface.

An outer edge of the outer skin may be releasably connectable to an outer edge of the mounting plate. The wireless device disposed within the wireless device skin may be a router or a WiFi access point.

An object of the disclosed embodiments is to provide a wireless device skin for personalizing the outer shell of a wireless communications device.

Another object is to provide a wireless device skin that allows for the unlimited personal customization of a removable skin or shell.

A further object is to provide a wireless device skin that allows for the selection of multiple skin patterns, colors, and visual formats.

Further objects include a wireless device skin that does not affect the performance of the wireless device.

Another object is to provide a wireless device skin that allows for the future adaptation of bendable visual materials.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 is an exploded view of a wireless device skin, according to one embodiment of the invention.

FIG. 2 is a perspective view of the wireless device skin of FIG. 1.

### DETAILED DESCRIPTION OF EMBODIMENTS

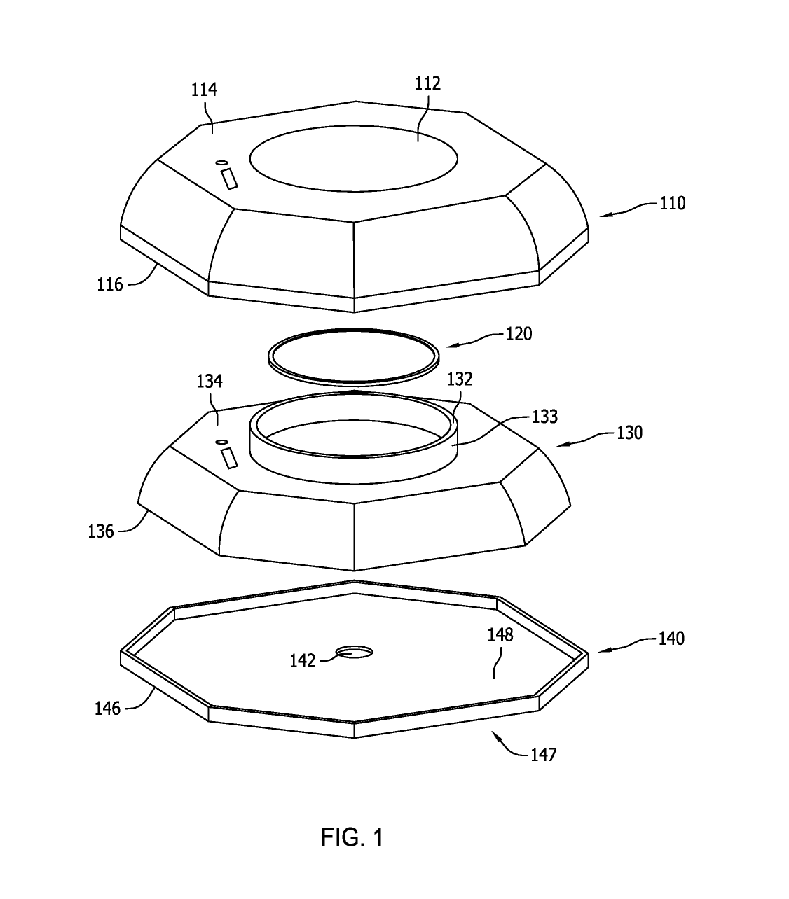

FIG. 1 is an exploded view of a wireless device skin, according to one embodiment of the invention. In FIG. 1, the wireless device skin includes an outer shell or skin 110, an inner shell 130 and a mounting plate 140. The outer skin 110 may be made of a flexible or inflexible material and is configured to mount to an outermost edge 146 of the mounting plate 140. In this embodiment, the outer skin 110 is shown in an octagon shape with a rounded surface extending from the mounting edge 116 of the skin 110. The outer skin 110, however, may take on a variety of other shapes such as circular, hexagonal, star-shaped, etc., as desired by an end user of the device.

The outer skin 110 may be formed from any suitable material that allows for the proper passage of predetermined radio frequencies. For example, in this embodiment, the outer skin 110 is configured to allow the passage of radio frequencies in the range of 10 MHz to 100 GHz bands. Such material may include Acrylonitrile butadiene styrene (ABS) plastic, fiberglass, glass, or other such materials. The thickness of the material is set so as not to interfere with the predetermined radio frequencies. In this embodiment, the thickness preferably does not exceed ⅛ inch to allow for the proper passage of signals.

The outer skin 110 is releasably connectable with the outside edge 146 of the mounting plate 140. Specifically, the outer mounting edge 116 of the outer skin 110 is releasably connected to the outside edge 146 of the mounting plate 140. For example, the connection between the outer skin 110 and the mounting plate 140 may be via clamps, fasteners, clips, etc. In this manner, skins with different colors, patterns, and other visible features may be easily switched and connected to the mounting plate 140.

The outer skin 110 further includes an aperture 112 in a center of the outer skin 110 that facilitates the pass through of a center disk 120. In some embodiments, the outer skin 110 may include control input access holes 114 which may allow control inputs of the wireless device to be accessed through the outer skin 110.

As shown in FIG. 1, the outer skin 110 is configured to cover an inner shell 130. The inner shell is configured to protect the internal components of the wireless device while a user swaps out the outer skin 110.

The inner shell 130 is preferably made of an ABS plastic, fiberglass, glass, or other material that allows for the proper passage of predetermined radio frequencies. As with the outer skin 110, the inner shell may be made in any suitable shape according to a user's desires. Preferably, the shape of the inner shell 130 is similar to the shape of the outer skin 110.

In this embodiment, the inner shell facilitates passage of radio frequencies from the 10 MHz to 100 GHz bands. In this instance, the thickness of the inner shell 130 is preferably less than 1/16 inch in thickness to allow for the proper passage of the radio frequencies. The inner shell 130 also protects the internal components of a wireless device from outside environmental exposure, and prevents users swapping out the outer skin 110 from being exposed to electronic circuits within the device.

The inner shell 130 also may have a central aperture 132 that allows access into the inner shell 130. A raised portion 133 may surround the aperture 132 and is configured to attach to the center disk 120. The center disk 120 may be configured to releasably connect to the raised portion 133 of the inner shell 130. In this manner, access to the wireless device may be maintained. The inner shell 130 may also include input access holes 134 that allow control inputs of the wireless device to extend through the inner shell 130 such that the control inputs are accessible through the wireless device skin.

The inner shell 130 may be releasably or permanently connected to the mounting plate 140. The lower edge 136 of the inner shell 130 is mounted to mounting plate 140 at a location inward from the edges 146 of the mounting plate. In this manner, the inner shell 130 is disposed within the outer skin 110.

The inner shell 130 and the mounting plate 110 may together be considered to form a protective housing in which the wireless device may be disposed. As explained above, the mounting plate 140 connects to both the outer skin 110 and the inner shell 130. The mounting plate is a substantially flat member having a first side 147 and a second side 148. The mounting plate 140 may include one or more mounting holes 142 that allow the first side 147 of the mounting plate 140 (and thus the protective housing) to be mounted on a surface, such as on a wall or ceiling. The mounting plate 140 may also comprise any number of features or accessories of the second side 148 to facilitate mounting of the wireless device thereon. Alternatively, the wireless device may be mounted on a lower side of the center disk 120 so that it extends down into the housing.

The mounting plate 120 may be formed from ABS plastic, fiberglass, glass, composites, or any metals. The mounting plate 120 may be formed in any suitable geometric shape. However, the mounting plate 120 preferably is formed in a similar shape as the outer skin 110. In this manner, the outer skin 110 and the inner shell 130 may easily attach to the second side 148 of the mounting plate 140.

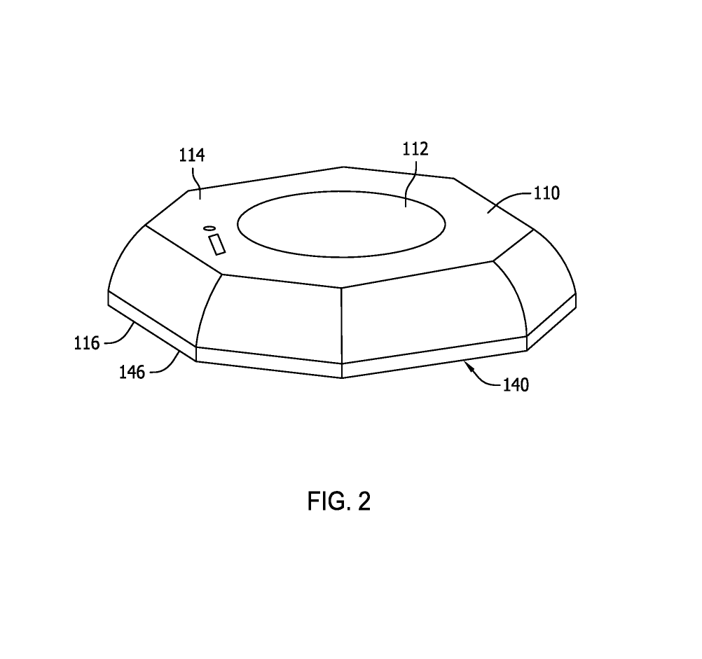

FIG. 2 is a perspective view of the wireless device skin of FIG. 1. As explained above, the mounting plate 140 connects to both the inner shell 130 and the outer skin 110. The center disk 120 closes the inner shell 130 and allows access to the wireless device when needed. The outer skin 110 may be replaced with a similar outer skin 110 to obtain different visual looks. In this manner, the look of the wireless device skin may be configured to match the environment, or to provide a means of expression by its owner.

Though many wireless devices like WiFi access points, femtocells, smallcells, and routers exist in homes or the commercial marketplace, all are typically one of two or three basic colors: black, white, grey, or combinations of the two. The disclosed embodiments allow a user to change the outer skin for a different outer skin having a different coating, paint, vinyl or other covering. The user may thus easily change the look and feel of the wireless device skin as desired.

In one embodiment, the skin is configured with logos, brands, or names of the location at which the wireless communication device is installed. For example, the wireless communication device may be located at sports arena or stadium and the skin may be configured with the logos, names, or brands of the stadium or the sports team(s) which play at the location.

In one embodiment, the skin is configured to be a color that matches the color of a wall, ceiling, or other surface on which the wireless communication device mounts. This allows the wireless communication device to blend in with the background on which it rests creating a more even and pleasing aesthetic appearance. The skin may be printed to color match using one or more codes from the paint or surface.

It is also contemplated that a picture of the surface to which the wireless communication device is to mount may be taken, and then that picture be used to print or create skin for the wireless communication device. This allows the skin to identically match a surface even if the surface has a pattern, text, or the pattern is complex.

It is also contemplated that the skin may be made with one or more sections that block radio waves thereby acting as a filter or shield for certain sectors of the wireless communication device. For example, the skin may be applied in sections and the section may block or diminish radio waves. By applying the skin, the radio waves may be prevented from extending into certain areas or locations. The skin may also be configured to pass only certain wavelengths, thereby acting as a filter to screen unwanted radio signals.

The skin may also be customizable to any look or theme, thereby allowing an owner of a wireless communication device to a wide array of different themes, colors, or images. This customization may not match any background or pattern, but be done to make the wireless communication device look more presentable or interesting. The themes may be sports, music based, movie or book related, or nature themed.

Advancements in vinyl development have led to new types of vinyl, designed specifically for wrap advertising—this includes vinyl that feature bubble-preventing air channels and microscopic glass beads that prevent an adhesive from functioning until the user is prepared (the beads allow the material to be repeatedly lifted and reapplied during the wrapping process, without compromising the longevity of the wrap). The vinyl may be heated with a heat gun or torch for the purpose of molding the material around objects.

Using what is known as a conformable vinyl wrapping material, a high-quality print or protective clear wrap can be molded to any and every part of an outer shell of a wireless communication device. The outer shell may be removed during the wrap process or the wrap may be installed with the shell in place. Typically, the wrap material is conformable because it is the easiest to work with, especially on contoured surfaces. Using the proper adhesives when applying the material to the surface of the car is necessary, otherwise the wrap can lead to adhesive failure in a few months after the application. Controltac™ graphic film may be one exemplary wrap product.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A wireless device skin that houses a wireless device, the wireless device skin comprising:
a mounting plate having a first side and a second side, the first side being mountable to a surface;
an inner shell that is mounted onto the second side of the mounting plate, the inner shell and the mounting plate forming a housing in which the wireless device is disposed, and the inner shell including a center aperture;
an outer skin that is releasably mounted onto the second side of the mounting plate, the outer skin covering the inner shell, and the outer skin including a center aperture; and
a center disk configured to pass through the center aperture of the outer skin and close the center aperture of the inner shell.

2. The wireless device skin according to claim 1, wherein the wireless device disposed within the housing is mounted to the second side of the mounting plate.

3. The wireless device skin according to claim 1, wherein the inner shell and the outer skin comprise control input holes allowing access to controls of the wireless device.

4. The wireless device skin according to claim 1, wherein the mounting plate includes at least one mounting hole facilitating the mounting plate being mounted to the surface.

5. The wireless device skin according to claim 1, wherein an outer edge of the outer skin is releasably connectable to an outer edge of the mounting plate.

6. The wireless device skin according to claim 1, wherein the wireless device is a router or a WiFi access point.

7. A method for changing the appearance of a wireless communication device comprising:
providing a wireless communication device including a transceiver operational within a frequency band, the transceiver located within an outer shell and a mounting plate;
providing a flexible skin having an outer surface and an inner surface covered by a protective layer, the skin having a thickness tailored to the frequency band;
adhesively connecting the inner surface of the skin to the outer shell to modify an appearance of the outer shell to an appearance of the outer surface of the skin.

8. The method of claim 7, further including providing an inner shell between the transceiver and the outer shell.

9. The method of claim 7, wherein the appearance of the outer surface of the skin is selected from the group consisting of a brand, a logo, a location, or a team name.

10. The method of claim 7, further including the skin being configured to reject a second frequency band, the second frequency band being a frequency band at which the transceiver does not operate.

11. The method of claim 7, wherein the skin includes at least a first layer that forms the outer surface and an inner layer that includes a metallic material.
